(19) United States
(12) Patent Application Publication
(10) Pub. No.: US 2019/0273168 A1
(43) Pub. Date: Sep. 5, 2019

(54) SEMICONDUCTOR DEVICE AND DISPLAY DEVICE

(71) Applicant: Sharp Kabushiki Kaisha, Sakai City, Osaka (JP)

(72) Inventor: Hiroshi MATSUKIZONO, Sakai City (JP)

(21) Appl. No.: 16/334,035

(22) PCT Filed: Sep. 12, 2017
(86) PCT No.: PCT/JP2017/032874

§ 371 Date: Mar. 18, 2019

(30) Foreign Application Priority Data
Sep. 20, 2016 (JP) 2016-183237

(51) Int. Cl. H01L 29/786; H01L 29/22; H01L 27/12

(52) U.S. Cl. CPC H01L 29/78696; H01L 27/1225; H01L 29/2206; H01L 29/78693

(57) ABSTRACT

Provided is a semiconductor device (100A) including: a substrate (1); a first gate electrode (2) that is provided on the substrate; a first gate insulating layer (3) that covers the first gate electrode; a first oxide semiconductor layer (4) that faces the first gate electrode with the first gate insulating layer in between; a first source electrode (5) and a first drain electrode (6) that are electrically connected to the first oxide semiconductor layer; a second gate insulating layer (7) that covers the first oxide semiconductor layer; a second gate electrode (8) that faces the first oxide semiconductor layer with the second gate insulating layer in between; a third gate insulating layer (9) that covers the second gate electrode; a second oxide semiconductor layer (10) that faces the second gate electrode with the third gate insulating layer in between; and a second source electrode (11) and a second drain electrode (12) that are electrically connected to the second oxide semiconductor layer.

### TECHNICAL FIELD

The present invention relates to a semiconductor device and particularly to a semiconductor device in which an oxide semiconductor layer is used as an activation layer of a TFT. Furthermore, the present invention also relates to a display device that includes such a semiconductor device as an active matrix substrate.

### BACKGROUND ART

An active matrix substrate that is used in a liquid crystal display device or the like includes a switching element, such as a thin film transistor (hereinafter referred to as “TFT”), for every pixel. As this switching element, a TFT (hereinafter referred to as “amorphous silicon TFT”) of which an activation layer is an amorphous silicon film, or a TFT (hereinafter referred to as “polycrystalline silicon TFT”) of which an activation layer is a polycrystalline silicon film has been widely used in the related art.

In recent years, it has been proposed that instead of amorphous silicon or polycrystalline silicon, an oxide semiconductor is used as a material of an activation layer of a TFT. Such a TFT is referred to as “oxide semiconductor TFT”. An active matrix substrate in which an In—Ga—Zn—O-based semiconductor film is used as an activation layer of a TFT is disclosed in PTL 1.

The oxide semiconductor has higher mobility than the amorphous silicon. For this reason, it is possible that the oxide semiconductor TFT operates at a higher speed than the amorphous silicon TFT. Furthermore, since the oxide semiconductor film is formed with a simpler process than the polycrystalline silicon film, the oxide semiconductor film can also find application in devices in each of which a large area is necessary.

On the other hand, techniques are known that monolithically (integrally) provide a drive circuit, such as a gate driver or a source driver, on a substrate. Normally, these drive circuits (monolithic drivers) are configured by using TFTs. In recent years, techniques for manufacturing a monolithic driver on a substrate using an oxide semiconductor TFT have been used. Accordingly, cost reduction is realized by narrowing down a frame area (frame narrowing) or simplifying a mounting process.

### CITATION LIST

### Patent Literature

PTL 1: Japanese Unexamined Patent Application Publication No. 2012-134475

### SUMMARY OF INVENTION

### Technical Problem

In recent years, there has been a demand for a further improvement in performance of an active matrix substrate, and there has been a requirement for a further increase in a drive capability of an oxide semiconductor TFT that is used as a switching element.

An object of the present invention, which is made in view of the problem described above, is to improve a drive capability of an oxide semiconductor TFT that is used in a semiconductor device.

### Solution to Problem

According to an embodiment of the present invention, there is provided a semiconductor device including: a substrate; a first gate electrode that is provided on the substrate; a first gate insulating layer that covers the first gate electrode; a first oxide semiconductor layer that is provided on the first gate insulating layer and faces the first gate electrode with the first gate insulating layer in between; a first source electrode and a first drain electrode that are electrically connected to the first oxide semiconductor layer; a second gate insulating layer that covers the first oxide semiconductor layer; a second gate electrode that is provided on the second gate insulating layer and faces the first oxide semiconductor layer with the second gate insulating layer in between; a third gate insulating layer that covers the second gate electrode; a second oxide semiconductor layer that is provided on the third gate insulating layer and faces the second gate electrode with the third gate insulating layer in between; and a second source electrode and a second drain electrode that are electrically connected to the second oxide semiconductor layer.

In a certain embodiment, the first source electrode and the second source electrode are electrically connected to each other, and the first drain electrode and the second drain electrode are electrically connected to each other.

In a certain embodiment, the first gate electrode, the first gate insulating layer, the first oxide semiconductor layer, the first source electrode, the first drain electrode, the second gate insulating layer, the second gate electrode, the third gate insulating layer, the second oxide semiconductor layer, the second source electrode, and the second drain electrode function as one oxide semiconductor TFT that includes the first oxide semiconductor layer and the second oxide semiconductor layer as an activation layer.

In a certain embodiment, the first source electrode and the second source electrode are not electrically connected to each other, and the first drain electrode and the second drain electrode are not electrically connected to each other.

In a certain embodiment, the first gate electrode, the first gate insulating layer, the first oxide semiconductor layer, the first source electrode, the first drain electrode, the second gate insulating layer, and the second gate electrode function as a first oxide semiconductor TFT that includes the first oxide semiconductor layer as an activation layer, and the second gate electrode, the third gate insulating layer, the second oxide semiconductor layer, the second source electrode, and the second drain electrode function as a second oxide semiconductor TFT that includes the second oxide semiconductor layer as an activation layer.

In a certain embodiment, the first source electrode and the second source electrode are electrically connected to each other, and the first drain electrode and the second drain electrode are not electrically connected to each other.

In a certain embodiment, the first source electrode and the second source electrode are not electrically connected to each other, and the first drain electrode and the second drain electrode are electrically connected to each other.

In a certain embodiment, the semiconductor device further includes a crystalline silicon TFT that includes a crystalline silicon semiconductor layer as an activation layer.

In a certain embodiment, the crystalline silicon TFT includes the crystalline silicon semiconductor layer that is provided in the substrate, the first gate insulating layer that covers the crystalline silicon semiconductor layer, a third gate electrode that is provided on the first gate insulating layer and faces the crystalline silicon semiconductor layer with the first gate insulating layer in between, and a third source electrode and a third drain electrode that are electrically connected to the crystalline silicon semiconductor layer.

In a certain embodiment, the first gate electrode is formed from an identical crystalline silicon film with the crystalline silicon semiconductor layer.

In a certain embodiment, each of the first oxide semiconductor layer and the second oxide semiconductor layer contains an In—Ga—Zn—O-based semiconductor.

In a certain embodiment, the In—Ga—Zn—O-based semiconductor contains a crystalline portion.

In a certain embodiment, a semiconductor device according to the present invention is an active matrix substrate that has a display area which includes multiple pixel areas and a non-display area which is positioned in a vicinity of the display area.

In a certain embodiment, a semiconductor device according to the present invention is an active matrix substrate that has a display area which includes multiple pixel areas and a non-display area which is positioned in a vicinity of the display area, in which the oxide semiconductor TFT is positioned in each of the multiple pixel areas.

In a certain embodiment, a semiconductor device according to the present invention is an active matrix substrate that has a display area which includes multiple pixel areas and a non-display area which is positioned in a vicinity of the display area, in which the crystalline silicon TFT is positioned in the non-display area.

According to another embodiment of the present invention, there is provided display device including: an active matrix substrate; a counter substrate that is positioned in such a manner as to face the active matrix substrate; and a display medium layer that is provided between the active matrix substrate and the counter substrate, in which the active matrix substrate is the semiconductor device.

### Advantageous Effects of Invention

According to the embodiment of the present invention, a drive capability of an oxide semiconductor TFT that is used in a semiconductor device can be improved.

### BRIEF DESCRIPTION OF DRAWINGS

FIG. 1 is a cross-sectional diagram schematically illustrating a semiconductor device 100A according to an embodiment of the present invention.

FIG. 2 is a cross-sectional diagram illustrating an oxide semiconductor TFT 920 that is a comparative example.

FIG. 3 is a cross-sectional diagram schematically illustrating a semiconductor device 100B according to an embodiment of the present invention.

FIG. 4 is a cross-sectional diagram schematically illustrating a semiconductor device unit 100C according to an embodiment of the present invention.

FIG. 5 is a cross-sectional diagram schematically illustrating a semiconductor device 100D according to an embodiment of the present embodiment.

FIGS. 6(a) to 6(e) are process-related cross-sectional diagrams illustrating processes of manufacturing the semiconductor device 100B.

FIGS. 7(a) to 7(c) are process-related cross-sectional diagrams illustrating processes of manufacturing the semiconductor device 100B.

FIGS. 8(a) and 8(b) are process-related cross-sectional diagrams illustrating processes of manufacturing the semiconductor device 100B.

FIG. 9 is a diagram schematically illustrating an active matrix substrate 200 according to an embodiment of the present invention.

FIG. 10 is a diagram schematically illustrating an active matrix substrate 300 according to an embodiment of the present invention.

FIG. 11 is a diagram for describing an arrangement of a gate driver 40M and terminal portions 42 and 52 in the active matrix substrate 300.

FIG. 12(a) is a diagram illustrating an example of a circuit that is equivalent to the gate driver 40M. FIG. 12(b) is a diagram illustrating an example in which the gate driver 40M is positioned within a pixel.

FIG. 13 is a diagram illustrating a signal waveform for driving the gate driver 40M.

FIG. 14 is a diagram illustrating another example of the circuit that is equivalent to the gate driver 40M.

FIG. 15 is a diagram schematically illustrating an active matrix substrate 400 according to an embodiment of the present invention.

### DESCRIPTION OF EMBODIMENTS

Embodiments of the present invention will be described below with reference to the drawings. It is noted that the present invention is not limited to the following embodiments.

### First Embodiment

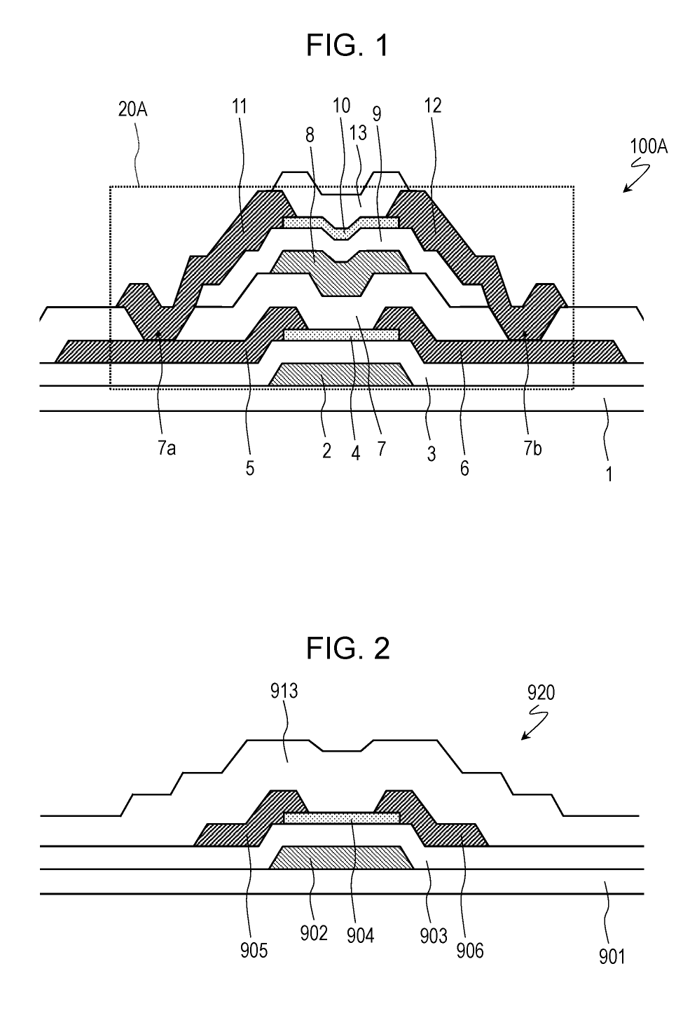

A configuration of a semiconductor device 100A according to the present embodiment is described with reference to FIG. 1. FIG. 1 is a cross-sectional diagram schematically illustrating the semiconductor device 100A.

The semiconductor device 100A, as illustrated in FIG. 1, includes a substrate 1, a first gate electrode 2, a first gate insulating layer 3, a first oxide semiconductor layer 4, a first source electrode 5, and a first drain electrode 6.

The substrate 1 has insulation properties, and for example, a glass substrate or a plastic substrate. Provided on the substrate 1 is a first gate electrode (hereinafter also referred to as “lower layer gate electrode”) 2. A first gate insulating layer (hereinafter also referred to as “lower layer gate insulating layer”) 3 is formed in such a manner as to cover the lower layer gate electrode 2.

Provided on the lower layer gate insulating layer 3 is a first oxide semiconductor layer (hereinafter also referred to as “lower layer oxide semiconductor layer”) 4. The lower layer oxide semiconductor layer 4 is positioned in such a manner as to face the lower layer gate electrode 2 with the lower layer gate insulating layer 3 in between.

The first source electrode (hereinafter also referred to as “lower layer source electrode”) 5 and the first drain electrode (hereinafter also referred to as “lower layer drain electrode”) 6 are formed on the lower layer gate insulating layer 3 and the lower layer oxide semiconductor layer 4, and are electrically connected to the lower layer oxide semiconductor layer 4.

The semiconductor device 100A further includes a second gate insulating layer 7, a second gate electrode 8, a third gate insulating layer 9, a second oxide semiconductor layer 10, a second source electrode 11, and a second drain electrode 12.

The second gate insulating layer (hereinafter also referred to as “intermediate layer gate insulating layer”) 7 is formed in such a manner as to cover the lower layer oxide semiconductor layer 4, the lower layer source electrode 5, and the lower layer drain electrode 6. Provided on the intermediate layer gate insulating layer 7 is the second gate electrode (hereinafter also referred to as “upper layer gate electrode”) 8. The upper layer gate electrode 8 is positioned in such a manner as to face the lower layer oxide semiconductor layer 4 with the intermediate layer gate insulating layer 7 in between.

The third gate insulating layer (hereinafter also referred to as “upper layer gate insulating layer”) 9 is formed in such a manner as to cover the upper layer gate electrode 8. Provided on the upper layer gate insulating layer 9 is a second oxide semiconductor layer (hereinafter also referred to as “upper layer oxide semiconductor layer”) 10. The upper layer oxide semiconductor layer 10 is positioned in such a manner as to face the upper layer gate electrode 8 with the upper layer gate insulating layer 9 in between.

The second source electrode (hereinafter also referred to as “upper layer source electrode”) 11 and the second drain electrode (hereinafter also referred to as “lower layer source electrode”) 12 are formed on the upper layer gate insulating layer 9 and the upper layer oxide semiconductor layer 10, and are electrically connected to the upper layer oxide semiconductor layer 10. A protective layer (a passivation layer) 13 is provided in such a manner as to cover the upper layer oxide semiconductor layer 10.

The lower layer source electrode 5 and the upper layer source electrode 11 are electrically connected to each other. In an example that is illustrated in FIG. 1, an opening portion 7a through which a portion of the lower layer source electrode 5 is exposed is formed in the intermediate layer gate insulating layer 7, and the upper layer source electrode 11 is brought into contact with the lower layer source electrode 5 within the opening portion 7a.

The lower layer drain electrode 6 and the upper layer drain electrode 12 are electrically connected to each other. In the example that is illustrated in FIG. 1, an opening portion 7b through which a portion of the lower layer drain electrode 6 is exposed is formed in the intermediate layer gate insulating layer 7, and the upper layer drain electrode 12 is brought into contact with the lower layer drain electrode 6 within the opening portion 7b.

The two gate electrodes (the lower layer gate electrode 2 and the upper layer gate electrode 8), the three gate insulating layers (the lower layer gate insulating layer 3, the intermediate layer gate insulating layer 7, and the upper layer gate insulating layer 9), the two oxide semiconductor layers (the lower layer oxide semiconductor layer 4 and the upper layer oxide semiconductor layer 10), the two source electrodes (the lower layer source electrode 5 and the upper layer source electrode 11), and the two drain electrodes (the lower layer drain electrode 6 and the upper layer drain electrode 12), which are described above, function as one oxide semiconductor TFT 20A.

The oxide semiconductor TFT 20A includes the lower layer oxide semiconductor layer 4 and the upper layer oxide semiconductor layer 10, as an activation layer. A conductive state and a non-conductive state between the lower layer source electrode 5 and the lower layer drain electrode 6 that are electrically connected to the lower layer oxide semiconductor layer 4 are controlled with an electric potential of the lower layer gate electrode 2 that is positioned below the lower layer oxide semiconductor layer 4, and an electric potential of the upper layer gate electrode 8 that is positioned above the lower layer oxide semiconductor layer 4. Furthermore, a conductive state and a non-conductive state between the upper layer source electrode 11 and the upper layer drain electrode 12 that are electrically connected to the upper layer oxide semiconductor layer 10 are controlled with the electric potential of the upper layer gate electrode 8 that is positioned below the upper layer oxide semiconductor layer 10.

The oxide semiconductor TFT 20A that is included in the semiconductor device 100A according to the present embodiment has a higher drive capability than an oxide semiconductor TFT with a general configuration. The reason for this will be described below in comparison with an oxide semiconductor TFT 920 that is a comparative example which is illustrated in FIG. 2.

The oxide semiconductor TFT 920 in the comparative example which is illustrated in FIG. 2 is a TFT having a general bottom gate structure. The oxide semiconductor TFT 920 is supported on a substrate 901, and has a gate electrode 902, a gate insulating layer 903, an oxide semiconductor layer 904, a source electrode 905, and a drain electrode 906.

The gate electrode 902 is provided on the substrate 901, and the gate insulating layer 903 is formed in such a manner as to cover the gate electrode 902. Provided on the gate insulating layer 903 is the oxide semiconductor layer 904. The oxide semiconductor layer 904 is positioned in such a manner as to face the gate electrode 902 with the gate insulating layer 903 in between. The source electrode 905 and the drain electrode 906 are formed on the gate insulating layer 903 and the oxide semiconductor layer 904, and are electrically connected to the oxide semiconductor layer 904. A protective layer (a passivation layer) 913 is provided in such a manner as to cover the oxide semiconductor layer 904, the source electrode 905, and the drain electrode 906.

In the semiconductor device 100A according to the present embodiment, four operation modes are defined in accordance with an electric potential that is given to the upper layer gate electrode 8 and an electric potential that is given to the lower layer gate electrode 2. In Table 1, electric potentials that are given to the upper layer gate electrode 8 and the lower layer gate electrode 2 in the four operation modes [1] to [4] are illustrated. “Off-electric potential” is a negative electric potential at which the oxide semiconductor layer enters the non-conductive state, and “on-electric potential” is a positive electric potential at which the oxide semiconductor layer enters the conductive state and is an electric potential of which an absolute value is higher than an absolute value of the off-electric potential. Furthermore, in Table 1, “on-electric current ratio” is also illustrated. The “on-electric current ratio” is a ratio for electric current values that are obtained in each operation mode in a case where electrostatic capacities of three gate insulating layers are assumed to be the same.

TABLE 1

| | | | On-electric |
|---|---|---|---|
| | | | current ratio |
| Operation | Upper layer | Lower layer | between |
| mode | gate electrode | gate electrode | S and D |
| [1] | Off-electric potential | Off-electric potential | 0 |
| [2] | Off-electric potential | On-electric potential | 1 |
| [3] | On-electric potential | Off-electric potential | 2 |
| [4] | On-electric potential | On-electric potential | 3 |

In the operation mode [1], the off-electric potential is given to both the upper layer gate electrode 8 and the lower layer gate electrode 2. At this time, because both the upper layer oxide semiconductor layer 10 and the lower layer oxide semiconductor layer 4 enter the non-conductive state, the on-electric current ratio is “0”.

In the operation mode [2], the off-electric potential is given to the upper layer gate electrode 8 and the on-electric potential is given to the lower layer gate electrode 2. At this time, because the upper layer oxide semiconductor layer 10 enters the non-conductive state, and the lower layer oxide semiconductor layer 4 enters the conductive state, the on-electric current ratio is “1”.

In the operation mode [3], the on-electric potential is given to the upper layer gate electrode 8, and the off-electric potential is given to the lower layer gate electrode 2. At this time, because both the upper layer oxide semiconductor layer 10 and the lower layer oxide semiconductor layer 4 enter the conductive state, the on-electric current ratio is “2”.

In the operation mode [4], the on-electric potential is given to both the upper layer gate electrode 8 and the lower layer gate electrode 2. At this time, both the upper layer oxide semiconductor layer 10 and the lower layer oxide semiconductor layer 4 enter the conductive state. Furthermore, because the lower layer oxide semiconductor layer 4 is influenced by the on-electric potentials of both the upper layer gate electrode 8 and the lower layer gate electrode 2, an electric current value between the lower layer source electrode 5 and the lower layer drain electrode 6 is twice the electric current value in the cases of the operation modes [2] and [3]. For this reason, the on-electric current ratio is “3”.

In contrast to this, in the oxide semiconductor TFT 920 in the comparative example, two operation modes are defined in accordance with an electric potential that is given to the gate electrode 902. In Table 2, an electric potential of the gate electrode 2 and the on-electric current ratio in the two operation modes [1] and [2] are illustrated.

TABLE 2

| Operation | | On-electric current ratio |
|---|---|---|
| mode | Gate electrode | between S and D |
| [1] | Off-electric potential | 0 |
| [2] | On-electric potential | 1 |

In the operation mode [1], the off-electric potential is given to the gate electrode 902. At this time, the oxide semiconductor layer 904 enters the non-conductive state, and because of this, the on-electric current ratio is “0” (a so-called off state is entered).

In the operation mode [2], the on-electric potential is given to the gate electrode 902, and at this time, the oxide semiconductor layer 904 enters the conductive state. Because of this, the on-electric current ratio is “1” (a so-called on state is entered).

As understood from the above description, in the semiconductor device 100A according to the present embodiment, the oxide semiconductor TFT 20A can be operated with a drive capability that is twice (the operation mode [3]) or operated with a drive capability that is three times (the operation mode [4]) the drive capability of the oxide semiconductor TFT 920 in the comparative example. Furthermore, the oxide semiconductor TFT 20A can also be operated at the same drive capability (the operation mode [2]) as the oxide semiconductor TFT 920 in the comparative example.

In this manner, according to the embodiment of the present invention, a drive capability of an oxide semiconductor TFT can be improved. It is noted that for easy understanding, the description is provided here using the “on-electric current ratio”, but that, of course, a magnitude of an on-electric current can be adjusted by changing a channel size (more specifically, a ratio W/L of a channel width W to a channel length L). According to the embodiment of the present invention, a large magnitude of the on-electric current can be obtained without increasing an area of the TFT (without increasing the channel size).

### Second Embodiment

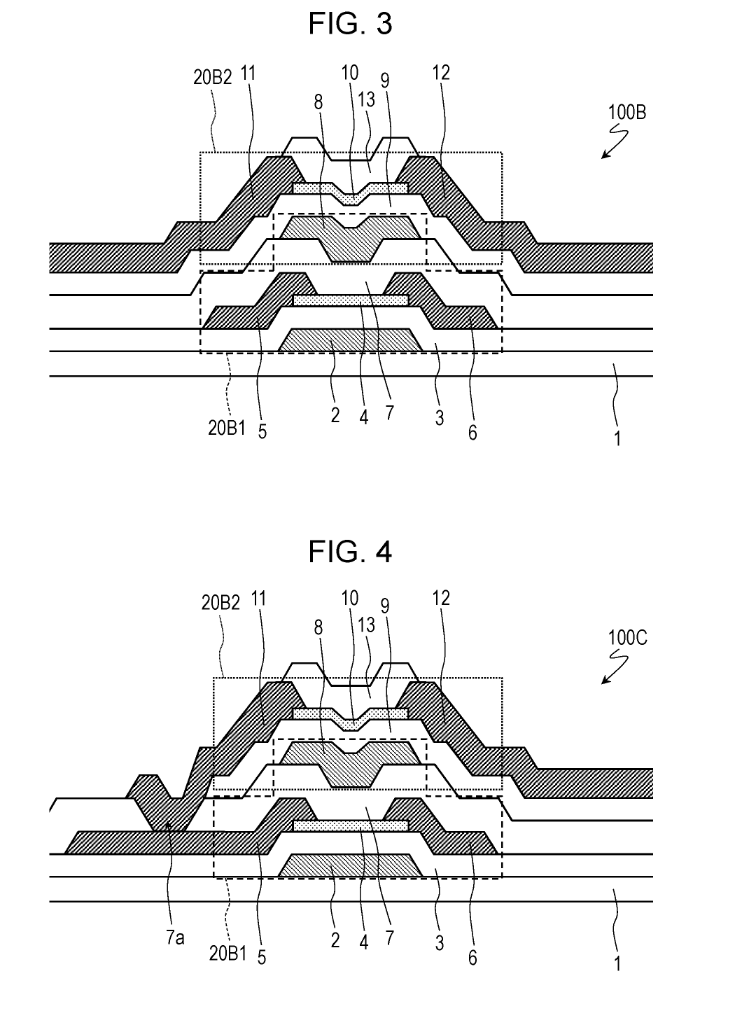

A semiconductor device 100B according to the present embodiment is described with reference to FIG. 3. FIG. 3 is a cross-sectional diagram illustrating schematically illustrating the semiconductor device 100B. What distinguishes the semiconductor device 100B from the semiconductor device 100A according to the first embodiment will be described below in an emphasized manner.

In the semiconductor device 100B that is illustrated in FIG. 3, the lower layer source electrode 5 and the upper layer source electrode 11 are not electrically connected to each other. Furthermore, the lower layer drain electrode 6 and the upper layer drain electrode 12 are not electrically connected to each other. For this reason, a constituent element on the substrate 1 functions as two oxide semiconductor TFTs 20B1 and 20B2 that result from stacking one on top of another.

Specifically, the lower layer gate electrode 2, the lower layer gate insulating layer 3, the lower layer oxide semiconductor layer 4, the lower layer source electrode 5, the lower layer drain electrode 6, the intermediate layer gate insulating layer 7, and the upper layer gate electrode 8 function as the first oxide semiconductor TFT 20B1. Furthermore, the upper layer gate electrode 8, the upper layer gate insulating layer 9, the upper layer oxide semiconductor layer 10, the upper layer source electrode 11, and the upper layer drain electrode 12 function as the second oxide semiconductor TFT 20B2.

The first oxide semiconductor TFT 20B1 includes the lower layer oxide semiconductor layer 4 as an activation layer. The conductive state and the non-conductive state between the lower layer source electrode 5 and the lower layer drain electrode 6 that are electrically connected to the lower layer oxide semiconductor layer 4 are controlled with an electric potential of the lower layer gate electrode 2 that is positioned below the lower layer oxide semiconductor layer 4, and the electric potential of the upper layer gate electrode 8 that is positioned above the lower layer oxide semiconductor layer 4.

The second oxide semiconductor TFT 20B2 includes the upper layer oxide semiconductor layer 10 as an activation layer. The conductive state and the non-conductive state between the upper layer source electrode 11 and the upper layer drain electrode 12 that are electrically connected to the upper layer oxide semiconductor layer 10 are controlled with the electric potential of the upper layer gate electrode 8 that is positioned below the upper layer oxide semiconductor layer 10.

In the semiconductor device 100B according to the present embodiment, four operation modes are defined in accordance with the electric potential that is given to the upper layer gate electrode 8 and the electric potential that is given to the lower layer gate electrode 2. In Table 3, in the four operation modes, the operation modes [1] to [4], electric potential of the upper layer gate electrode 8 and the lower layer gate electrode 2, an on-electric current ratio (an on-electric current ratio between lower layer S and D) for the first oxide semiconductor TFT 20B1, and an on-electric current ratio (an on-electric current ratio between upper layer S and D) for the second oxide semiconductor TFT 20B2.

TABLE 3

| | | | On-electric | On-electric |
|---|---|---|---|---|
| | | | current ratio | current ratio |
| | | | between | between |
| Operation | Upper layer | Lower layer | lower layer | upper layer |
| mode | gate electrode | gate electrode | S and D | S and D |
| [1] | Off-electric | Off-electric | 0 | 0 |
| | potential | potential | | |
| [2] | Off-electric | On-electric | 1 | 0 |
| | potential | potential | | |
| [3] | On-electric | Off-electric | 1 | 1 |
| | potential | potential | | |
| [4] | On-electric | On-electric | 2 | 1 |
| | potential | potential | | |

In the operation mode [1], the off-electric potential is given to both the upper layer gate electrode 8 and the lower layer gate electrode 2. At this time, because both the upper layer oxide semiconductor layer 10 and the lower layer oxide semiconductor layer 4 enter the non-conductive state, both the on-electric current ratio for the first oxide semiconductor TFT 20B1 and the on-electric current ratio for the second oxide semiconductor TFT 20B2 are “0”.

In the operation mode [2], the off-electric potential is given to the upper layer gate electrode 8 and the on-electric potential is given to the lower layer gate electrode 2. At this time, because the upper layer oxide semiconductor layer 10 enters the non-conductive state and the lower layer oxide semiconductor layer 4 enters the conductive state, the on-electric current ratio for the first oxide semiconductor TFT 20B1 is “1”, and the on-electric current ratio for the second oxide semiconductor TFT 20B2 is “0”.

In the operation mode [3], the on-electric potential is given to the upper layer gate electrode 8, and the off-electric potential is given to the lower layer gate electrode 2. At this time, because both the upper layer oxide semiconductor layer 10 and the lower layer oxide semiconductor layer 4 enter the conductive state, both the on-electric current ratio for the first oxide semiconductor TFT 20B1 and the on-current ratio for the second oxide semiconductor TFT 20B2 are “1”.

In the operation mode [4], the on-electric potential is given to both the upper layer gate electrode 8 and the lower layer gate electrode 2. At this time, both the upper layer oxide semiconductor layer 10 and the lower layer oxide semiconductor layer 4 enter the conductive state. Furthermore, because the lower layer oxide semiconductor layer 4 is influenced by the on-electric potentials of both the upper layer gate electrode 8 and the lower layer gate electrode 2, an electric current value between the lower layer source electrode 5 and the lower layer drain electrode 6 is twice the electric current value in the cases of the operation modes [2] and [3]. For this reason, the on-electric current ratio for the first oxide semiconductor TFT 20B1 is “2”, and the on-electric current ratio for the second oxide semiconductor TFT 20B2 is “1”.

As understood from the above description, in the semiconductor device 100B according to the present embodiment, the first oxide semiconductor TFT 20B1 can be operated with a drive capability that is twice the drive capability of the oxide semiconductor TFT 920 in the comparative example (the operation mode [4]). Furthermore, only the first oxide semiconductor TFT 20B1 or both the first oxide semiconductor TFT 20B1 and the second oxide semiconductor TFT 20B2 can also be operated at the same drive capability (the operation modes [2] and [3]) as the oxide semiconductor TFT 920 in the comparative example.

In this manner, in the present embodiment, the drive capability of the oxide semiconductor TFT can also be improved. Furthermore, because two oxide semiconductor TFTs (the first oxide semiconductor TFT 20B1 and the second oxide semiconductor TFT 20B2) are stacked one on top of another, an effect of decreasing a ratio of an area occupied by the TFT area to an area of the substrate 1 can also be obtained.

### Third Embodiment

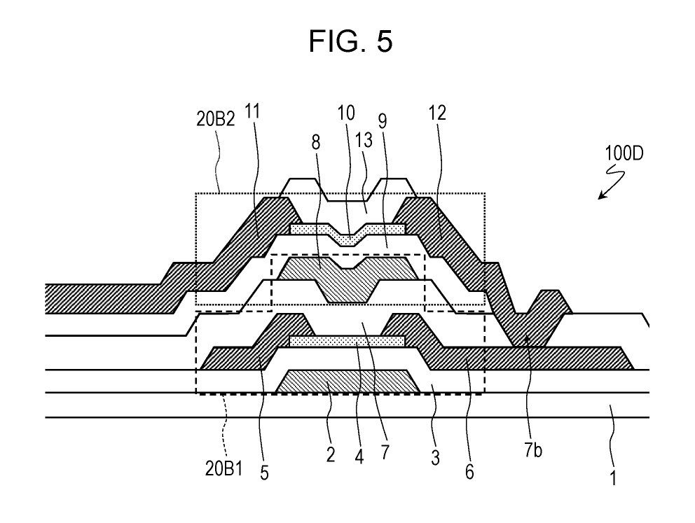

Configurations of semiconductor devices 100C and 100D according to the present embodiment are described with reference to FIGS. 4 and 5. FIG. 4 is a cross-sectional diagram schematically illustrating the semiconductor device 100C. FIG. 5 is a cross-sectional diagram schematically illustrating the semiconductor device 100D. What distinguishes the semiconductor devices 100C and 100D from the semiconductor device 100B according to the second embodiment will be described below in an emphasized manner.

In the semiconductor device 100C that is illustrated in FIG. 4, the lower layer source electrode 5 and the upper layer source electrode 11 are electrically connected to each other. In an example that is illustrated in FIG. 4, the opening portion 7a through which a portion of the lower layer source electrode 5 is exposed is formed in the intermediate layer gate insulating layer 7, and the upper layer source electrode 11 is brought into contact with the lower layer source electrode 5 within the opening portion 7a. On the other hand, the lower layer drain electrode 6 and the upper layer drain electrode 12 are not electrically connected to each other. Therefore, a constituent element on the substrate 1 functions as two oxide semiconductor TFTs (the first oxide semiconductor TFT 20B1 and the second oxide semiconductor TFT 20B2) of which source electrodes are shared (of which source electrodes are electrically connected).

In the semiconductor device 100D that is illustrated in FIG. 5, the lower layer drain electrode 6 and the upper layer drain electrode 12 are electrically connected to each other. In an example that is illustrated in FIG. 5, the opening portion 7b through which a portion of the lower layer drain electrode 6 is exposed is formed in the intermediate layer gate insulating layer 7, and the upper layer drain electrode 12 is brought into contact with the lower layer drain electrode 6 within the opening portion 7b. On the other hand, the lower layer source electrode 5 and the upper layer source electrode 11 are not electrically connected to each other. Therefore, a constituent element on the substrate 1 functions as two oxide semiconductor TFTs (the first oxide semiconductor TFT 20B1 and the second oxide semiconductor TFT 20B2) of which drain electrodes are shared (of which drain electrodes are electrically connected).

In the semiconductor devices 100C and 100D according to the embodiment, the four operation modes that are the same as those for the semiconductor device 100B according to the second embodiment are also defined in accordance with the electric potential that is given to the upper layer gate electrode 8 and the electric potential that is given to the lower layer gate electrode 2 (refer to Table 3). For this reason, in the semiconductor devices 100C and 100D according to the present embodiment, the first oxide semiconductor TFT 20B1 can also be operated with a drive capability that is twice the drive capability of the oxide semiconductor TFT 920 in the comparative example (the operation mode [4] in Table 3). Furthermore, only the first oxide semiconductor TFT 20B1 or both the first oxide semiconductor TFT 20B1 and the second oxide semiconductor TFT 20B2 can also be operated at the same drive capability (the operation modes [2] and [3] in Table 3) as the oxide semiconductor TFT 920 in the comparative example.

In this manner, in the present embodiment, the drive capability of the oxide semiconductor TFT can also be improved. Furthermore, because two oxide semiconductor TFTs (the first oxide semiconductor TFT 20B1 and the second oxide semiconductor TFT 20B2) are stacked one on top of another, the effect of decreasing a ratio of an area occupied by the TFT area to an area of the substrate 1 can also be obtained.

[Method of Manufacturing the Semiconductor Devices According to the First to Third Embodiments]

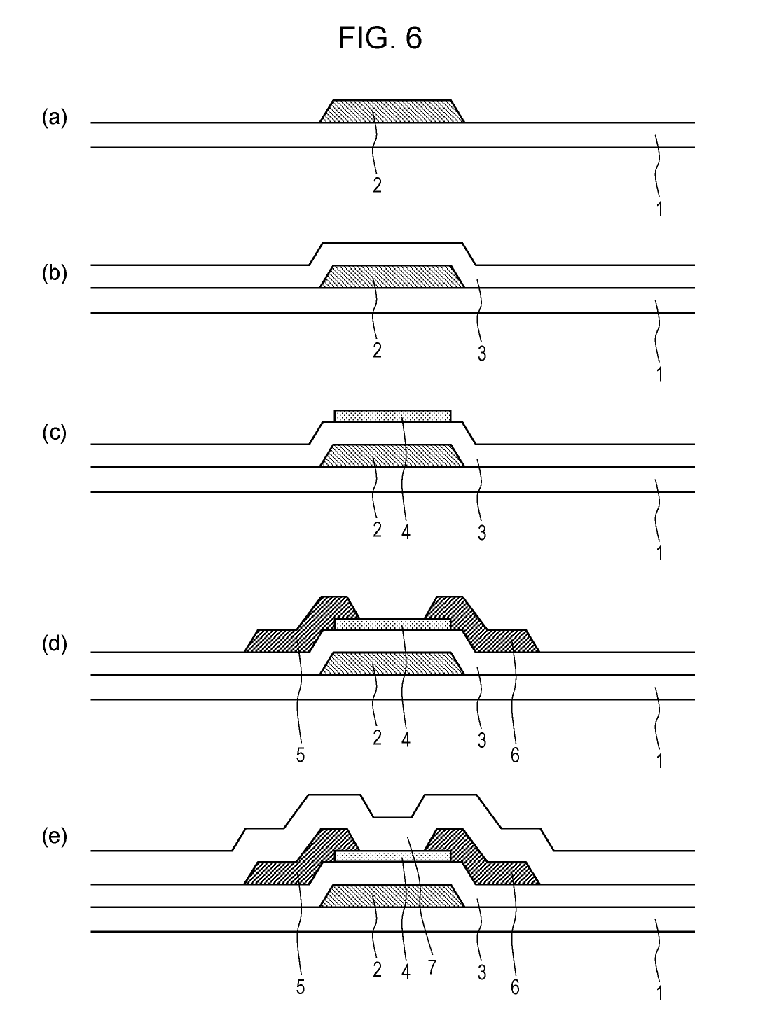

The semiconductor devices 100A to 100D according to the first to third embodiments, for example, can be manufactured as follows. As an example, the semiconductor device 100B according to the second embodiment is described here. FIGS. 6(a) to 6(e), 7(a) to 7(c), and 8(a) and 8(b) are process-related cross-sectional diagrams illustrating processes of manufacturing the semiconductor device 100B.

First, as illustrated in FIG. 6(a), the lower layer gate electrode 2 is formed on the substrate 1. For example, a glass substrate can be used as the substrate 1. To obtain the lower layer gate electrode 2, a lower layer gate conductive film (the thickness thereof is equal to greater than 50 nm and is equal to or smaller than 500 nm) is formed on the substrate 1 using a sputtering method and the lower layer gate conductive film is patterned using a photolithography process. As the lower layer gate conductive film, a film that contains a metal, such as aluminum (Al), tungsten (W), molybdenum (Mo), tantalum (Ta), chrome (Cr), titanium (Ti), or copper (Cu), an alloy of these, or a metal nitride of these can be suitably used. Furthermore, a multi-layered film that results from stacking these multiple films may be used. At this point, as the lower layer gate conductive film, a multi-layered film that results from forming a Cu film and a Ti film in this order is used.

Next, as illustrated in FIG. 6(b), the lower layer gate insulating layer (the thickness thereof is equal to or greater than 200 nm and is equal to or smaller than 500 nm) 3, in such a manner to cover the lower layer gate electrode 2, using a CVD method or the like. As the lower layer gate insulating layer 3, a silicon oxide (SiOx) layer, a silicon nitride (SiNx) layer, a silicon-oxide-nitride (SiOxNy; x>y) layer, a silicon nitride oxide (SiNxOy; x>y) layer, or the like can be suitably used. The lower layer gate insulating layer 3 may have a multi-layered structure. At this point, as the lower layer gate insulating layer 3, a multi-layered film, of which a lower layer is the SiNx layer and of which an upper layer is the SiOx layer, is formed.

Subsequently, as illustrated in FIG. 6(c), an oxide semiconductor film is formed on the lower layer gate insulating layer 3 and this oxide semiconductor film (the thickness thereof, for example, is equal to or greater than 10 nm and is equal to or smaller than 200 nm) is patterned using the photolithography process. Thus, the lower layer oxide semiconductor layer 4 is formed. The oxide semiconductor film may have a multi-layered structure.

Thereafter, as illustrated in FIG. 6(d), a lower layer source conductive film (the thickness thereof, for example, is equal to or greater than 50 nm and is equal to or smaller than 500 nm) on the lower layer gate insulating layer 3 and the lower layer oxide semiconductor layer 4, and this lower layer source conductive film is patterned using the photolithography process. Thus, the lower layer source electrode 5 and the lower layer drain electrode 6 that are brought into contact with the lower layer oxide semiconductor layer 4 are formed. As the lower layer source conductive film, a film that contains a metal, such as aluminum (Al), tungsten (W), molybdenum (Mo), tantalum (Ta), chrome (Cr), titanium (Ti), or copper (Cu), an alloy of these, or a metal nitride of these can be suitably used. Furthermore, a multi-layered film that results from stacking these multiple films may be used. At this point, as the lower layer source conductive film, a multi-layered film that results from forming a Cu film and a Ti film in this order is used.

Next, as illustrated in FIG. 6(e), the intermediate layer gate insulating layer 7 (the thickness thereof, for example, is equal to or greater than 200 nm and is equal to or smaller than 500 nm) is formed in such a manner as to cover the lower layer oxide semiconductor layer 4, the lower layer source electrode 5, and the lower layer drain electrode 6, for example, using the CVD method. As the intermediate layer gate insulating layer 7, a silicon oxide (SiOx) film, a silicon nitride (SiNx) film, a silicon-oxide-nitride (SiOxNy; x>y) film, a silicon nitride oxide (SiNxOy; x>y) film, and the like can be suitably used. The intermediate layer gate insulating layer 7 may have a multi-layered structure. At this point, as the intermediate layer gate insulating layer 7, a multi-layered film, of which an upper layer is the SiNx layer and of which a lower layer is the SiOx layer, is formed.

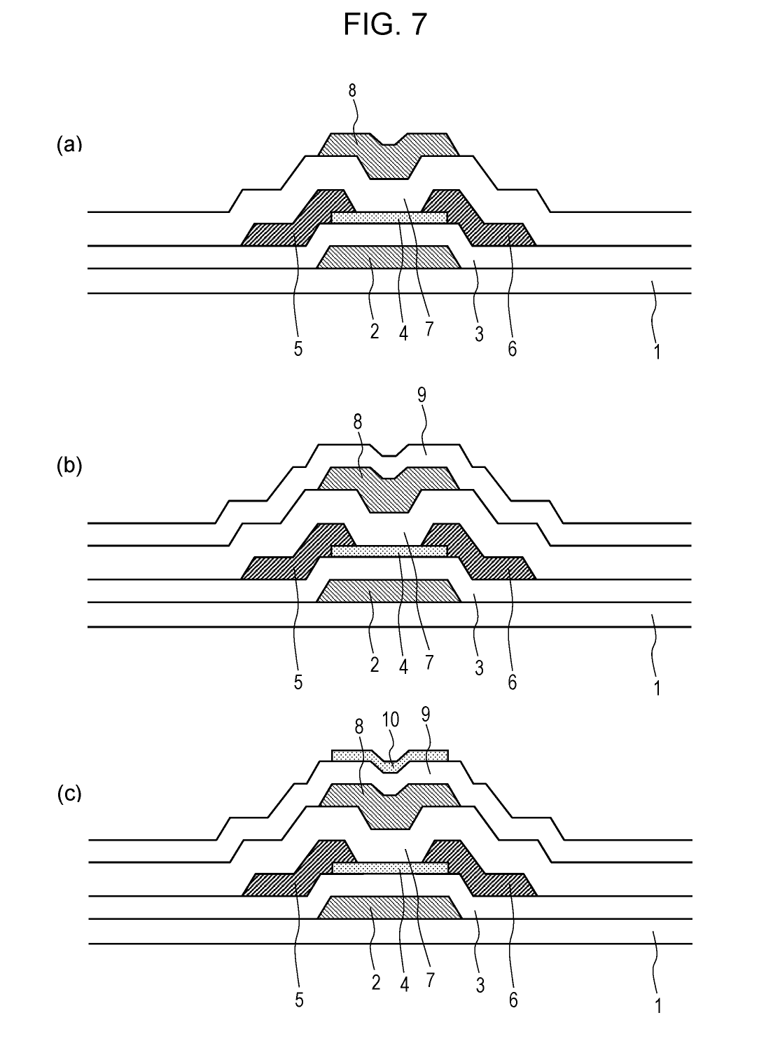

Subsequently, as illustrated in FIG. 7(a), the upper layer gate electrode 8 is formed on the intermediate layer gate insulating layer 7. To obtain the upper layer gate electrode 8, an upper layer gate conductive film (the thickness thereof, for example, is equal to or greater than 50 nm and is equal to or smaller than 500 nm) is formed the substrate 1 using the sputtering method, and this upper layer gate conductive film is patterned using the photolithography process. As the upper layer gate conductive film, a film that contains a metal, such as aluminum (Al), tungsten (W), molybdenum (Mo), tantalum (Ta), chrome (Cr), titanium (Ti), or copper (Cu), an alloy of these, or a metal nitride of these can be suitably used. Furthermore, a multi-layered film that results from stacking these multiple films may be used. At this point, as the upper layer gate conductive film, a multi-layered film that results from forming a Cu film and a Ti film in this order is used.

Thereafter, as illustrated in FIG. 7(b), the upper layer gate insulating layer (the thickness thereof, for example, is equal to or greater than 200 nm and is equal to or smaller than 500 nm) 9 is formed in such a manner as to cover the upper layer gate electrode 8, using the CVD method or the like. As the upper layer gate insulating layer 9, a silicon oxide (SiOx) layer, a silicon nitride (SiNx) layer, a silicon-oxide-nitride (SiOxNy; x>y) layer, a silicon nitride oxide (SiNxOy; x>y) layer, or the like can be suitably used. The upper layer gate insulating layer 9 may have a multi-layered structure. At this point, as the upper layer gate insulating layer 9, a multi-layered film, of which a lower layer is the SiNx layer and of which an upper layer is the SiOx layer, is formed.

Next, as illustrated in FIG. 7(c), an oxide semiconductor film is formed on the upper layer gate insulating layer 9, and this oxide semiconductor film (the thickness thereof, for example, is equal to or greater than 10 nm and is equal to or smaller than 200 nm) is patterned using the photolithography process. Thus, the upper layer oxide semiconductor layer 9 is formed. The oxide semiconductor film may have a multi-layered structure.

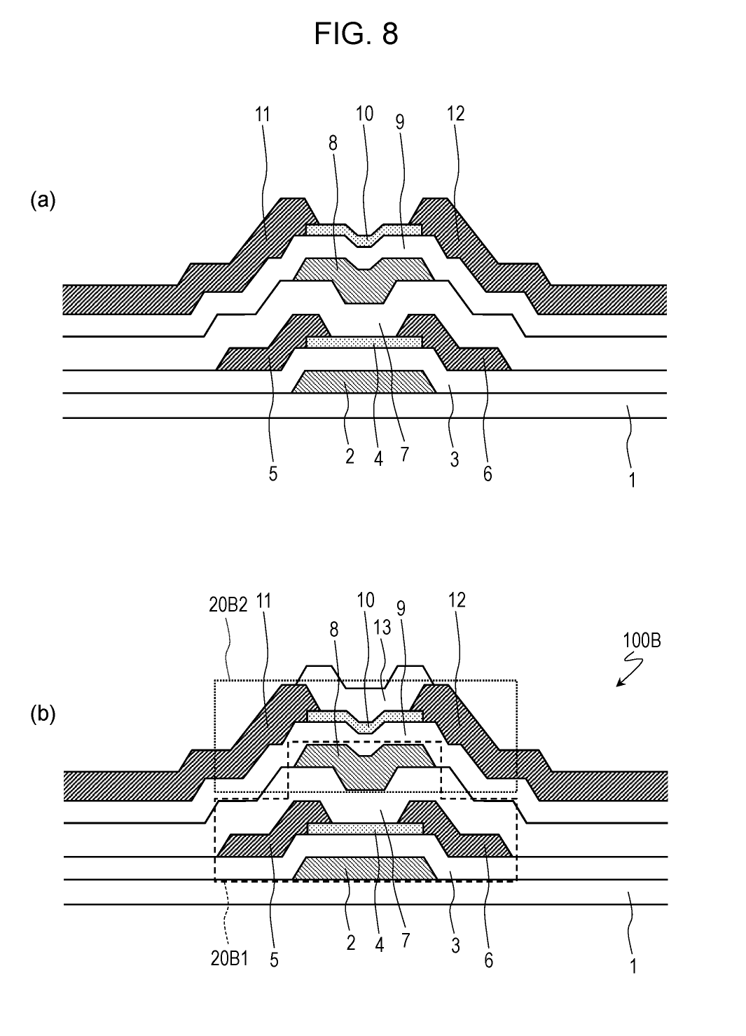

Subsequently, as illustrated in FIG. 8(a), an upper layer source conductive film (the thickness thereof, for example, is equal to or greater than 50 nm and is equal to or smaller than 500 nm) is formed on the upper layer gate insulating layer 9 and the upper layer oxide semiconductor layer 10, and this upper layer source conductive film is patterned using the photolithography process. Thus, the upper layer source electrode 11 and the upper layer drain electrode 12 that are brought into contact with the upper layer oxide semiconductor layer 10 are formed. As the upper layer source conductive film, a film that contains a metal, such as aluminum (Al), tungsten (W), molybdenum (Mo), tantalum (Ta), chrome (Cr), titanium (Ti), or copper (Cu), an alloy of these, or a metal nitride of these can be suitably used. Furthermore, a multi-layered film that results from stacking these multiple films may be used. At this point, as the upper layer source conductive film, a multi-layered film that results from forming a Cu film and a Ti film in this order is used.

Thereafter, as illustrated in FIG. 8(b), the protective layer (the passivation layer) 13 (the thickness thereof, for example, is equal to or greater than 100 nm and is equal to or smaller than 500 nm, preferably, is equal to or greater than 150 nm and is equal to or smaller than 500 nm) is formed in such a manner as to cover the upper layer oxide semiconductor layer 10, for example, using the CVD method. As the protective layer 13, a silicon oxide (SiOx) film, a silicon nitride (SiNx) film, a silicon-oxide-nitride (SiOxNy; x>y) film, a silicon nitride oxide (SiNxOy; x>y) film, or the like can be used. The protective layer 13 may have a multi-layered structure. At this point, as the protective layer 13, a multi-layered film, of which an upper layer is the SiNx layer and of which a lower layer is the SiOx layer, is formed.

In this manner, the active matrix substrate 100B can be manufactured.

[Oxide Semiconductor]

An oxide semiconductor that is contained in the lower layer oxide semiconductor layer 4 and the upper layer oxide semiconductor layer 10 may be an amorphous oxide semiconductor and may be a crystalline oxide semiconductor that has a crystalline portion. As the crystalline oxide semiconductor, a polycrystalline oxide semiconductor, a micro-crystalline oxide semiconductor, a crystalline oxide semiconductor in which a c-axis aligns approximately vertically with a layer surface, or the like is given.

The lower layer oxide semiconductor layer 4 and the upper layer oxide semiconductor layer 10 each may have a multi-layered structure in which two or more layers are involved. In a case where the lower layer oxide semiconductor layer 4 has a multi-layered structure, the lower layer oxide semiconductor layer 4 may include a non-crystalline oxide semiconductor layer and a crystalline oxide semiconductor layer, may include multiple crystalline oxide semiconductor layers that have different crystalline structures, and may include multiple non-crystalline oxide semiconductor layers. In the same manner, in a case where the upper layer oxide semiconductor layer 10 has a multi-layered structure, the upper layer oxide semiconductor layer 10 may include a non-crystalline oxide semiconductor layer and a crystalline oxide semiconductor layer, may include multiple crystalline oxide semiconductor layers that have different crystalline structures, and may include multiple non-crystalline oxide semiconductor layer.

Materials and structures of the non-crystalline oxide semiconductor and each of the crystalline oxide semiconductors described above, a film formation method, a structure of the oxide semiconductor layer that has a multi-layered structure, and the like, for example, are described in Japanese Unexamined Patent Application Publication No. 2014-007399. For reference, the entire contents of Japanese Unexamined Patent Application Publication No. 2014-007399 is incorporated in the present specification by reference.

The lower layer oxide semiconductor layer 4 and the upper layer oxide semiconductor layer 10 each may include, for example, at least one type of metal element among In, Ga, and Zn. The lower layer oxide semiconductor layer 4 and the upper layer oxide semiconductor layer 10 here includes, for example, an In—Ga—Zn—O-based semiconductor (for example, oxide indium gallium zinc). The In—Ga—Zn—O-based semiconductor here is a ternary oxide material that consists of Indium (In), Gallium (Ga), and Zinc (Zn). A ratio (a composition ratio) among In, Ga, and Zn is not particularly limited. Examples of the ratio include In:Ga:Zn=2:2:1, In:Ga:Zn=1:1:1, In:Ga:Zn=1:1:2, and the like. This oxide semiconductor layer can be formed from an oxide semiconductor film that contains an In—Ga—Zn—O-based semiconductor.

The In—Ga—Zn—O-based semiconductor may be amorphous and may be crystalline (may contain a crystalline portion). A crystalline in-Ga—Zn—O-based semiconductor in which a c-axis aligns approximately vertically with a layer surface is preferable as a crystalline In—Ga—Zn—O-based semiconductor.

It is noted that a crystalline structure of the crystalline In—Ga—Zn—O-based semiconductor, for example, is disclosed in Japanese Unexamined Patent Application Publication Nos. 2014-007399, 2012-134475, and 2014-209727, which are described above, and other publications. For reference, the entire contents of Japanese Unexamined Patent Application Publication Nos. 2012-134475 and 2014-209727 are incorporated in the present specification by reference. A TFT that has an In-GA-Zn—O-based semiconductor layer has high mobility (which is more than 20 times higher than that of an a-Si TFT) and a small amount of leak current (which is less than one-hundredth of that of the a-Si TFT). Because of this, the TFT is suitably used as a drive TFT (for example, a TFT that is included in a drive circuit which is provided on the same substrate as a display area, in the vicinity of the display area that includes multiple pixels) and a pixel TFT (a TFT that is provided in a pixel).

Instead of the In—Ga—Zn—O-based semiconductor, the lower layer oxide semiconductor layer 4 and the upper layer oxide semiconductor layer 10 each may include any other oxide semiconductor and may include, for example, an In—Sn—Zn—O-based semiconductor (for example, In₂O₃—SnO₂—ZnO; InSnZnO). The In—Sn—Zn—O-based semiconductor is a ternary oxide material that consists of Indium (In), Tin (Sn), and Zinc (Zn). Alternatively, the lower layer oxide semiconductor layer 4 and the upper layer oxide semiconductor layer 10 each may contain an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, CdO (cadmium oxide), a Mg—Zn—O-based semiconductor, an In—Ga—Sn—O-based semiconductor, an In—Ga—O-based semiconductor, a Zr—In—Zn—O-based semiconductor, a Hf—In—Zn—O-based semiconductor, an Al—Ga—Zn—O-based semiconductor, a Ga—Zn—O-based semiconductor, or the like.

### Fourth Embodiment

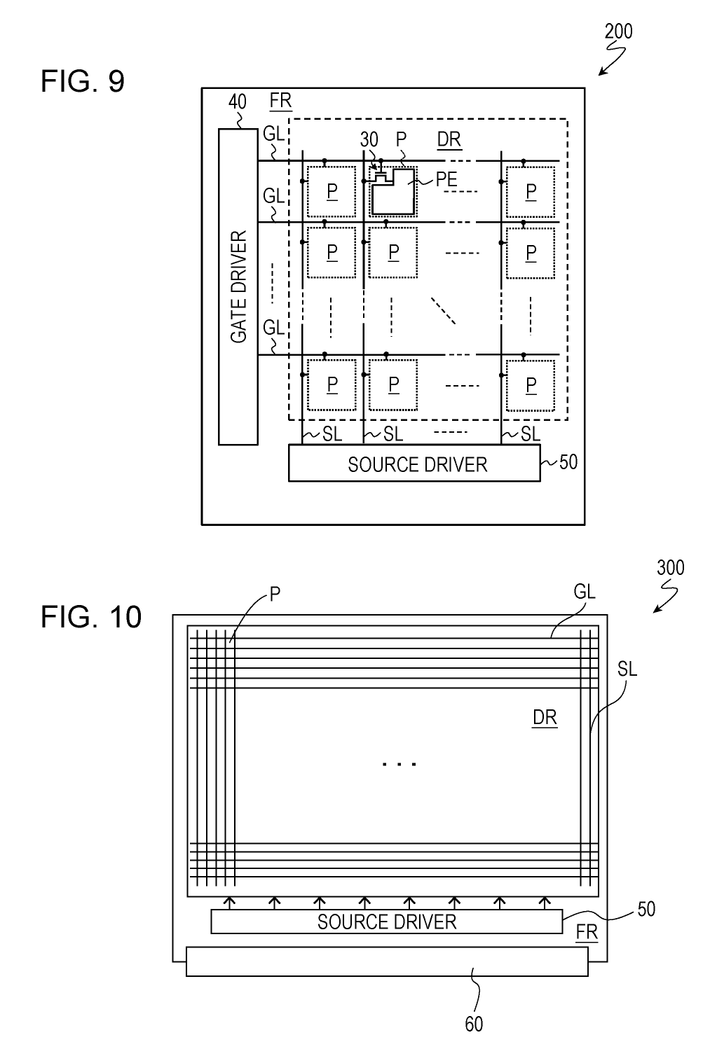

A semiconductor device according to an embodiment of the present invention is suitably used as an active matrix substrate (a TFT substrate) for a display device. FIG. 9 illustrates an active matrix substrate 200 according to the present embodiment.

The active matrix substrate 200, as illustrated in FIG. 9, has a display area DR and a non-display area FR. The display area DR includes multiple pixel areas P. The pixel area P is an area that corresponds to a pixel in a display device, and, in the specification in the present patent application, is also referred to simply as a “pixel”. The non-display area (a frame area) FR is positioned in the vicinity of the display area DR (more precisely, is an area other than the display area DR).

Multiple TFTs 30 are arranged within the display area DR. The TFT 30 is provided on every pixel. The TFT 30 is also referred to as “pixel TFT”. Furthermore, multiple gate wiring lines GL and multiple source wiring lines SL are arranged within the display area DR. The multiple gate wiring lines GL extend in the row direction. In contrast to this, the multiple source wiring lines SL extend in the column direction. In each pixel TFT 30, a scanning signal (a gate signal) is supplied from a corresponding gate wiring line GL, and a display signal (a source signal) is supplied from a corresponding source wiring line SL. Furthermore, in each pixel P, a pixel electrode PE that is electrically connected to the pixel TFT 30 is provided.

A gate driver 40 and a source driver 50 are arranged in the non-display area FR. The gate driver 40 is a drive circuit (a scan line drive circuit) that drives multiple gate wiring lines GL. The source driver 50 is a drive circuit (a signal line drive circuit) that drives multiple source wiring lines SL. At least one of the gate driver 40 and the source driver 50 may be a monolithic driver that is monolithically (integrally) formed in the active matrix substrate 200. The monolithic driver (a monolithic gate driver or a monolithic source driver) is configured to include multiple circuit TFTs.

For example, the oxide semiconductor TFT 20A according to the first embodiment can find application as the pixel TFT 30. By using the oxide semiconductor TFT 20A, a large magnitude of the on-electric current can be obtained without increasing a ratio of an area occupied by the pixel TFT 30 within the pixel P. Therefore, even in a case where high speed driving (for example, 120 Hz driving or 240 Hz driving) is performed, each pixel P can be sufficiently charged. For this reason, it is possible that the high speed driving is performed without decreasing an aperture ratio.

Furthermore, as multiple circuit TFTs that constitute the monolithic driver, the configurations according to the first to third embodiments can be suitably used in combination. As understood from the description that is already provided, various operation mode can be realized depending on whether or not the source and drain electrodes on the upper layer and lower layer are shared, or by changing combinations of the electric potentials that are given to each of the upper layer gate electrode and lower layer gate electrode. For this reason, by suitably selecting the configurations according to the first to third embodiments, it is possible that an area of the monolithic driver is decreased. For this reason, further frame-narrowing can be realized.

At least a portion of the monolithic driver may be positioned within the display area DR. By employing this configuration, the non-display area FR can be further decreased (further frame-narrowing can be achieved). A configuration in which at least a portion of the monolithic driver is positioned in the display area DR, for example, is disclosed in International Publication No. 2014/069529. For reference, the entire contents of International Publication No. 2014/069529 are incorporated in the present specification by reference.

In FIG. 10, an active matrix substrate 300 that has a monolithic gate driver within the display area DR is illustrated.

The source driver 50 and an FPC substrate 60 are mounted in the non-display area FR of the active matrix substrate 300. Furthermore, a terminal portion, an SSD circuit, an inspection circuit, and the like can be provided in the non-display area FR.

Although not illustrated here, a gate driver (a monolithic gate driver) is formed in the display area DR in such a manner as to extend across multiple pixels P. Each gate wiring line GL is connected to each terminal of the gate driver. Each source wiring line SL is connected to each terminal of the source driver 50.

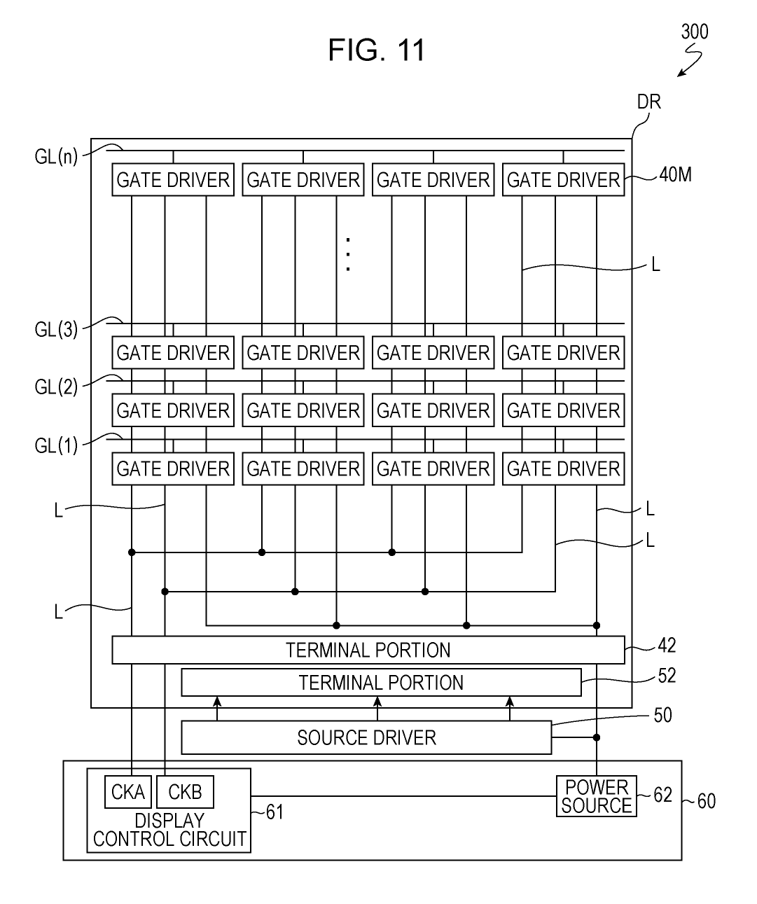

FIG. 11 is a diagram for describing an arrangement of a gate driver 40M and terminal portions 42 and 52 in the active matrix substrate 300. For simplification, the source wiring line SL is omitted.

As illustrated in FIG. 11, the gate driver 40M is formed between each of the gate wiring lines GL(1) to GL(n) that are arranged in the display area DR. In this example, four gate drivers 40M are connected to each of the gate wiring lines GL.

The source driver 50 and the FPC substrate 60 on which a display control circuit 61 and a power source 62 are formed are mounted in the non-display area FR. Furthermore, the terminal portion (a first terminal portion) 42 through which various signals are supplied to the gate driver 40M, and the terminal portion (a second terminal portion) 52 through which the source driver 50 and the source wiring line SL are connected to each other are mounted in the non-display area FR. The source driver 50 outputs a data signal to each source wiring line SL according to a control signal that is input from the display control circuit 61.

The terminal portion 42 is connected to the display control circuit 61 and the power source 62. The terminal portion 42 receives control signals (CKA and CKB) that are output from the control circuit 61 or a power source voltage signal that are output from the power source 62. Signals, such as the control signals (CKA and CKB) and the power source voltage signal, that are input into the terminal portion 42 are supplied to each gate driver 40M through drive circuit wiring L. According to a signal that is supplied, the gate driver 40M not only outputs a voltage signal that represents one of a selection state and a non-selection state to the gate wiring line GL that is connected, but also outputs its voltage signal to a gate wiring line GL in the next stage. In the following description, in some cases, the voltage signal that corresponds to each of the selection state and the non-selection state is referred to as a scanning signal. Furthermore, a state where the gate wiring line GL is selected is referred to as driving of the gate wiring line GL.

In an example that is illustrated in FIG. 11, within the display area DR, multiple gate drivers 40M are connected to each of the gate wiring lines GL. The gate drivers 40M that are connected to the same gate wiring line GL are synchronized, and the gate wiring lines GL are driven with scanning signals that are output from the gate drivers 40M, respectively.

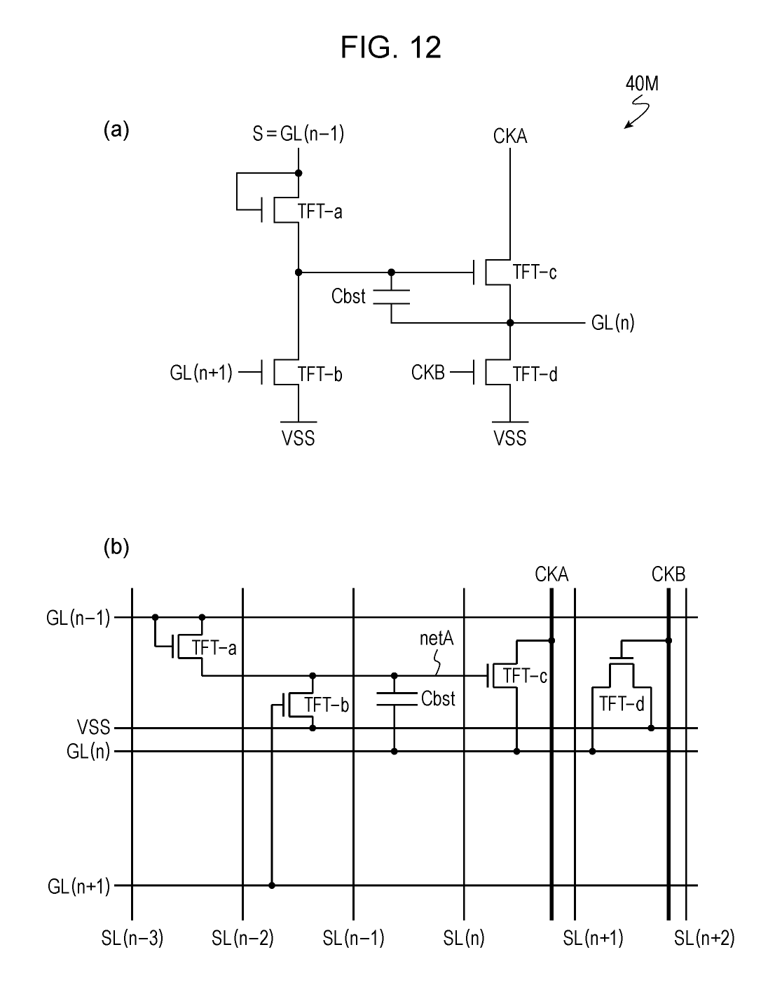

FIG. 12(a) is a diagram illustrating an example of a circuit that is equivalent to the gate driver 40M. The gate driver 40M includes a TFT-a for precharging a net A that is an internal node of the gate driver 40M, a TFT-b for discharging electric charge of the internal node net A, a TFT-c that is an output transistor for supplying a signal to the gate wiring line GL, a TFT-d for retaining electric potential of the gate wiring line GL, and a capacitor Cbst that is formed between the internal node net A and the gate wiring line GL. Input terminals for clock signals (CKA and CKB), power wiring for supplying power (VSS), and the like are connected to the gate driver 40M.

In FIG. 12(b), an example is illustrated in which the equivalent circuit that is illustrated in FIG. 12(a) is positioned within a pixel. In FIG. 12(b), a pixel TFT and a pixel circuit are omitted.

The gate driver 40M is positioned over multiple pixels. Multiple TFTs and the capacitors Cbst that constitute the gate driver 40M are arranged in different pixels, respectively. Each TFT and the capacitor Cbst are connected with drive circuit wiring that extends across a pixel.

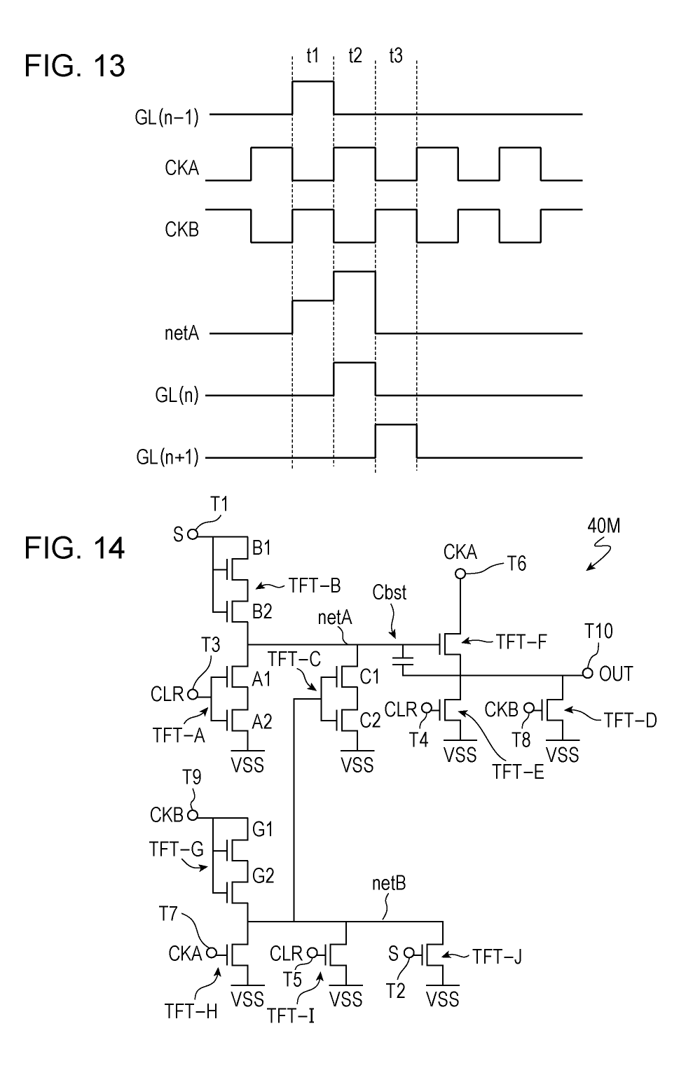

FIG. 13 is a diagram illustrating a signal waveform for driving the gate driver 40M. First, during duration t1, an (n−1)-th gate signal S in the previous stage is input into the TFT-a of an n-th gate driver, and the internal node net A is precharged. At this time, the TFT-c and the TFT-d enters an ON state, CKA is at Low electric potential (VSS). Because of this, the gate wiring line GL(n) is charged with Low electric potential (VSS).

Next, during duration t2, CKA switches to High electric potential (VDD), and CKB switches to Low electric potential (VSS). At this time, because the TFT-c is in an ON state and the TFT-d is in an OFF state, the gate wiring line GL(n) is charged with High electric potential (VDD) of CKA. Not only is the gate wiring line GL(n) charged, but the internal node (net A) is further pushed up to high electric potential through the capacitor Cbst. Accordingly, a sufficiently high voltage for charging the gate wiring line with High electric potential (VDD) can be applied to a gate electrode of TFT-c. Furthermore, during this duration, a signal of the gate wiring line GL(n) is input into an (n+1)-th gate driver in the next stage, and an internal node thereof is precharged.

Subsequently, during duration t3, CKA switches to Low electric potential (VSS), and CKB switches to High electric potential (VDD). Accordingly, the gate wiring line GL(n) is discharged to Low electric potential (VSS) through the TFT-d. Furthermore, at this time, the (n+1)-th gate wiring line in the next stage is charged with High electric potential (VDD). Because of this, the TFT-b enters an ON state and the internal node (net A) is discharged to VSS electric potential. Thus, operation of an (n)-th gate wiring line GL(n) is completed. Thereafter, until an operation is again performed with the next frame, VSS electric potential is input into the gate wiring line GL(n) through the TFT-d, in accordance with operation of CKB and a Low state is maintained.

FIG. 14 is a diagram illustrating another example of a circuit that is equivalent to the gate driver 40M. The gate driver 40M that is illustrated in FIG. 14 is positioned between an (n−1)-th gate wiring line GL(n−1) and an (n−2)-th gate wiring line GL(n−2), and drives an (n−1)-th gate wiring line GL(n−1). The gate driver 40M has a TFT-A to a TFT-J that are circuit TFTs, the capacitor Cbst, multiple terminals, terminals T1 to T10 through which a signal such as the clock signal is supplied, and the terminal group through which the power source voltage signal at a low level is input.

Through the terminals T1 and T2, a set signal (S) is received along a gate wiring line GL(n−2) in the previous stage. It is noted that through the terminal T1 and T2 that are connected the gate wiring line GL(1) in the initial stage (the first row), a gate start pulse signal (S) that is output from the display control circuit 61 is received. Through the terminals T3 to T5, a reset signal (CLR) that is output from the display control circuit 61 is received. Through the terminals T6 and T7, a clock signal (CKA) that is input is received. Through the terminals T8 and T9, a clock signal (CKB) that is input is received. Through the terminal T10, an output signal (OUT) is output to the gate wiring line GL(n−1).

The clock signal (CKA) and the clock signal (CKB) are two-phase clock signals that are phase-inverted for one horizontal scanning duration. In FIG. 14, the gate driver 40M that drives the (n−1)-th gate wiring line GL(n−1) is illustrated. However, in the gate driver 40M in a following stage, which drives the n-th gate wiring line GL(n), the terminals T6 and T7 receive the clock signal (CKB), and the terminal T8 and T9 receives the clock signal (CKA). More precisely, through the terminal T6 and T7 of each gate driver 40M, the clock signal that is received through the terminal T6 and T7 of the gate driver 40M in a neighboring row and the phase-inverted clock signal are received. Through the terminals T8 and T9 of each gate driver 40M, the clock signal that is received through the terminals T8 and T9 of the gate driver 40M in a neighboring row and the phase-inverted clock signal are received.

In FIG. 14, wiring to which a source terminal of the TFT-B, a drain terminal of the TFT-A, a source terminal of the TFT-C, one electrode of the capacitor Cbst, and a gate terminal of a TFT-F are connected is referred to as a net A. Furthermore, wiring to which a gate terminal of the TFT-C, a source terminal of a TFT-G, a drain terminal of a TFT-H, a source terminal of a TFT-I, a source terminal of a TFT-J are connected is referred to as a net B.

The TFT-A is configured by connecting two TFTs (A1 and A2) in series. Each gate terminal of the TFT-A is connected to the terminal T3, a drain terminal of the μl is connected to the net A, and a source terminal of the A2 is connected to a power source voltage terminal VSS.

The TFT-b is configured by connecting two TFTs (B1 and B2) in series. Each gate terminal of the TFT-B and a drain terminal of the B1 are connected to the terminal T1 (a diode connection), and a source terminal of the B2 is connected to the net A.

The TFT-C is configured by connecting two TFTs (C1 and C2) in series. Each gate terminal of the TFT-C is connected to the net B, a drain terminal of the C1 is connected to the net A, and a source terminal of the C2 is connected to the power source voltage terminal VSS.

One electrode of the capacitor Cbst is connected to the net A, and the other electrode is connected to the terminal T10.

A gate terminal of a TFT-D is connected to the terminal T8. A drain terminal and a source terminal of the TFT-D are connected to the terminal T10 and the power source voltage terminal VSS, respectively.

A gate terminal of a TFT-E is connected to the terminal T4. A drain terminal and a source terminal of the TFT-E are connected to the terminal T10 and the power source voltage terminal VSS, respectively.

A gate terminal of a TFT-F is connected to the net A. A drain terminal and a source terminal of the TFT-F are connected to terminal T6 and the terminal T10, respectively.

A TFT-G is configured by connecting two TFTs (G1 and G2) in series. Each gate terminal of the TFT-G and a drain terminal of the G1 are connected to a terminal 119 (the diode connection), and a source terminal of the G2 is connected to the net B.

A gate terminal of a TFT-H is connected to a terminal 117. A drain terminal and a source terminal of the TFT-H are connected to the net B and the power source voltage terminal VSS, respectively.

A gate terminal of a TFT-I is connected to a terminal 115. A drain terminal and a source terminal of the TFT-I are connected to the net B and the power source voltage terminal VSS, respectively.

A gate terminal of a TFT-J is connected to a terminal 112. A drain terminal and a source terminal of the TFT-J are connected to the net B and the power source voltage terminal VSS, respectively.

It is noted that in FIG. 14, an example is illustrated in which a TFT-A, a TFT-B, a TFT-C, and a TFT-G each are configured by connecting two TFTs in series, but that these may be configured with one TFT.

For multiple TFTs that constitute the gate driver 40M that is illustrated in FIGS. 12 and 14, the configurations of the semiconductor devices 100A to 100D according to the first to third embodiments can be used. For example, the oxide semiconductor TFT 20A of the semiconductor device 100A according to the first embodiment can be used as an output transistor (the TFT-c in an example that is illustrated in FIG. 12, or the TFT-F in an example that is illustrated in FIG. 14) for supplying a signal to the gate wiring line GL.

A high drive capability is required of the output transistor. For this reason, in the related art, in a case where the drive capability of the TFT is low, there is a need to use multiple TFTs as the output transistor and to arrange these to multiple places (multiple pixels) in a distributed manner in order to secure the pixel aperture ratio. In contrast to this, according to the embodiment of the present invention embodiment, it is possible that while securing the pixel aperture ratio, the gate driver 40M is formed at a higher density. For example, the oxide semiconductor TFT 20A according to the first embodiment obtains an on-electric current that is three times the on-electric current of the oxide semiconductor TFT 920 in the comparative example, and because of this, a function for which an arrangement in three places in a distributed manner is unnecessary in the related art can be realized with an arrangement in one place. Therefore, a circuit area (a circuit width) of the gate driver 40M can be decreased much more greatly. As a result, the degree of freedom in a shape of the display area DR can be increased, and for example, application in displays in an arbitrary shape, such as a circular shape, can also be possible.

### Fifth Embodiment

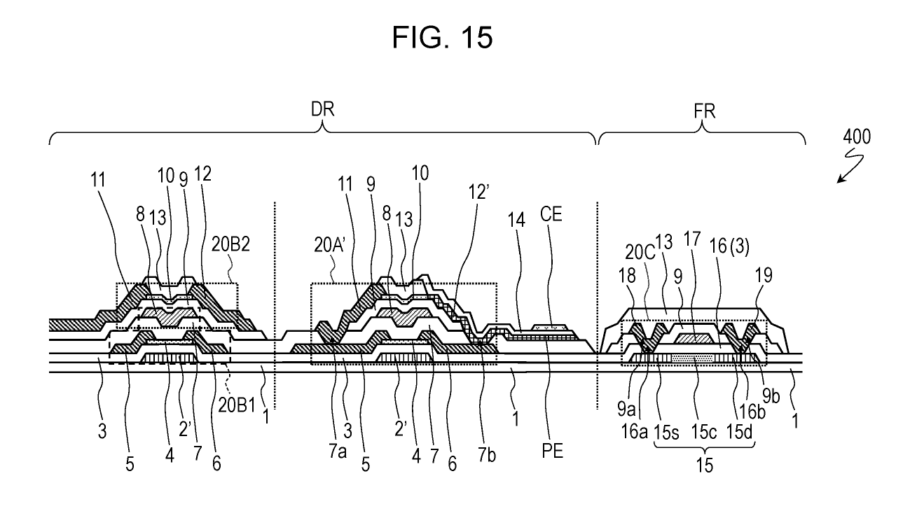

An active matrix substrate 400 according to the present embodiment is described with reference to FIG. 15. FIG. 15 is a cross-sectional diagram schematically illustrating the active matrix substrate 400. The active matrix substrate 400 that is illustrated here is used in a liquid crystal display device that operates in a Fringe Field Switching (FFS) mode. The FFS mode is a display mode in compliance with a transverse electric field method in which a pair of electrodes are provided on one substrate and in which an electric field is applied, in a direction (in the horizontal direction) parallel to a substrate surface, to liquid crystal molecules.

As illustrated in FIG. 15, the active matrix substrate 400 includes oxide semiconductor TFT 20A′, 20B1, and 20B2 that are arranged within the display area DR. Furthermore, the active matrix substrate 400 includes a crystalline silicon TFT 20C that is positioned within the non-display area FR and includes a crystalline silicon semiconductor layer 15 as an activation layer.

The oxide semiconductor TFT 20A′ functions as a pixel TFT. A lower layer drain electrode 6 and an upper layer drain electrode 12′ of the oxide semiconductor TFT 20A′ are electrically connected to the pixel electrode PE. The pixel electrode PE is provided on the intermediate layer gate electrode 7. A dielectric layer 14 is formed in such a manner as to cover the pixel electrode PE, and common electrode CE is provided on the dielectric layer 14. The common electrode CE is made of a transparent conductive material (for example, ITO), and faces the pixel electrode PE with the dielectric layer 14 in between. Although not illustrated here, the common electrode CE has at least one slit (an opening portion).

The oxide semiconductor TFT 20A′ is different from the oxide semiconductor TFT 20A′ according to the first embodiment in that the upper layer drain electrode 12′ is not formed from an upper layer source conductive film. The upper layer drain electrode 12′ and the pixel electrode PE are formed by lowering the resistance of a portion of an oxide semiconductor film for forming the upper layer oxide semiconductor layer 10. As processing (resistance lowering processing) for lowering a portion of the oxide semiconductor film, for example, plasma processing, or p type impurity or n type impurity doping, or the like can be used. Alternatively, a reduction insulation layer may be formed that has a property of reducing an oxide semiconductor, in such a manner as to be brought into contact with a portion of the oxide semiconductor film. A technique for the lowering of the resistance, which is described above, for example, is disclosed in International Publication Nos. 2013/115050, 2013/115051, and 2013/115052. For reference, the entire contents of International Publication Nos. 2013/115050, 2013/115051, and 2013/115052 are incorporated in the present specification by reference.

The oxide semiconductor TFT 20B1 and 20B2 function as the circuit TFT that constitutes the monolithic gate driver which is positioned within the display area DR. In FIG. 15, the oxide semiconductor TFT 20B1 and 20B2 that have the same configurations as the oxide semiconductor TFT 20B1 and 20B2, respectively, that are included in the semiconductor device 100B according to the second embodiment. However, the monolithic gate driver may include a circuit TFT that has the same configuration as the oxide semiconductor TFT 20B1 and 20B2 that are included in the semiconductor device 100C and 100D according to the third embodiment, and may include a circuit TFT that has the configuration as the oxide semiconductor TFT 20A that is included in the semiconductor device 100A according to the first embodiment.

The crystalline silicon TFT 20C functions as the circuit TFT that constitutes a source switching (Source Shared Driving (SSD)) circuit. The SSD circuit is a circuit that distributes video data from one video signal line that runs from each terminal of the source driver, to multiple source wiring lines.

The crystalline silicon TFT 20C includes the crystalline silicon semiconductor layer 15, a gate insulating layer 16, a gate electrode 17, a source electrode 18, and a drain electrode 19.

The crystalline silicon semiconductor layer 15 is provided on the substrate 1. The gate insulating layer 16 is formed in such a manner as to cover the crystalline silicon semiconductor layer 15. At this point, the lower layer gate insulating layer 3 that is formed in the display area DR extends up to the non-display area FR, and functions as the gate insulating layer 16.

The gate electrode 17 is provided on the gate insulating layer 16. The gate electrode 17 is positioned in such a manner as to face the crystalline silicon semiconductor layer 15 with the gate insulating layer 16 in between. At this point, the gate electrode 17 is formed from the same conductive film (more precisely, an upper layer gate conductive film) as the upper layer gate electrode 8 in the display area DR. The gate electrode 17 is covered with the upper layer gate insulating layer 9.

The source electrode 18 and the drain electrode 19 are formed on the upper layer gate insulating layer 9 and is electrically connected to the crystalline silicon semiconductor layer 15. At this point, opening portions 16a and 9a through which a portion (a source region 15s that will be described below) of the crystalline silicon semiconductor layer 15 is exposed is formed in the gate insulating layer 16 and the upper layer gate insulating layer 9, and within the opening portions 16a and 9a, the source electrode 18 is brought into contact with the crystalline silicon semiconductor layer 15. Furthermore, opening portions 16b and 9b through which any other portion (a drain region 15d that will be described below) of the crystalline silicon semiconductor layer 15 is exposed is formed in the gate insulating layer 16 and the upper layer gate insulating layer 9, and within the opening portions 16b and 9b, the drain electrode 19 is brought into contact with the crystalline silicon semiconductor layer 15.

The source electrode 18 and the drain electrode 19 are formed from the same conductive film (more precisely, an upper layer source conductive film) as the upper layer source electrode 11 and the upper layer drain electrode 12 in the display area DR. The source electrode 18 and the drain electrode 19 is covered with the protective layer (the passivation layer) 13.

The crystalline silicon semiconductor layer (for example, a polycrystalline silicon semiconductor layer) 15 has a region (an activation region) 15c in which a channel is formed, and the source region 15s and the drain region 15d that are positioned to both the sides, respectively, of the activation region. In this example, a portion that overlaps the gate electrode 17 with the gate insulating layer 16 in between, of the crystalline silicon semiconductor layer 15 is the activation region 15c.

For example, a non-crystalline silicon (a-Si) film is formed, and then the a-Si film is crystallized, thereby forming a crystalline silicon film. Thus, the crystalline silicon semiconductor layer 15 is formed by patterning the crystalline silicon film. The formation of the a-Si film can be performed, for example, using a known method such as a Chemical Vapor Deposition (CVD) method or a sputtering method. The crystallization of the a-Si film may be performed, for example, by illuminating the a-Si film with excimer laser light. Impurities are implanted into a portion of the formed the crystalline silicon semiconductor layer 15, and thus the source region 15s and the drain region 15d can be formed. An area into which the impurities are not implanted, of the crystalline silicon semiconductor layer 15 is the activation region (the channel region) 15c.

In the present embodiment, a lower layer gate electrode 2′ of each of the oxide semiconductor TFT 20A′ and 20B1 is formed from the same crystalline silicon film as the crystalline silicon semiconductor layer 15 of the crystalline silicon TFT 20C. The lower layer gate electrode 2′, for example, is an n+ type crystalline silicon layer that is obtained by implanting the impurities into the crystalline silicon film.

In the active matrix substrate 400 that has the configuration described above uses the oxide semiconductor TFT 20A′ as a pixel TFT, and because of this, a large magnitude of the on-electric current can be obtained without increasing the ratio of the area occupied by the pixel TFT within the pixel. Therefore, even in a case where high speed driving (for example, 120 Hz driving or 240 Hz driving) is performed, each pixel can be sufficiently charged. For this reason, it is possible that the high speed driving is performed without decreasing the aperture ratio.

Furthermore, for multiple circuit TFTs that constitute the monolithic gate driver, various operation mode can be realized depending on whether or not the source and drain electrodes on the upper layer and lower layer are shared, or by changing combinations of the electric potentials that are given to each of the upper layer gate electrode and lower layer gate electrode. Because of this, these are suitably selected, and thus a circuit area (a circuit width) of the monolithic gate driver that is formed within the display area DR can be decreased. As a result, the degree of freedom in a shape of the display area DR can be increased, and for example, application in displays in an arbitrary shape, such as a circular shape, can also be possible.

Furthermore, in the present embodiment, the lower layer gate electrode 2′ of each of the oxide semiconductor TFT 20A′ and 20B1 is formed from the same crystalline silicon film as the crystalline silicon semiconductor layer 15 of the crystalline silicon TFT 20C. By employing these structures, it is possible that an increase in the number of manufacturing processes or in manufacturing cost is suppressed when multiple types of TFTs (a polycrystalline silicon TFT and an oxide semiconductor TFT) are integrally formed on the same substrate 1.

Moreover, in the present embodiment, the pixel electrode PE is formed by lowering the resistance of a portion of an oxide semiconductor film. By employing this structure, the number of manufacturing processes or the manufacturing cost can be reduced.

(Display Device)

The active matrix substrate according to the embodiment of the present invention is used suitably in display devices. The display device can include an active matrix substrate according to the embodiment of the present invention, a counter substrate that is positioned in such a manner as to face the active matrix substrate, and a display medium layer that is provided between the active matrix substrate and the counter substrate. It is noted that the active matrix substrate of the liquid crystal display device that performs display in a transverse electric field mode such as the FFS mode has so far been described as an example, but can also find application as an active matrix substrate of a liquid crystal display device that performs display in a vertical electric field mode (for example, a TN mode or a vertical alignment mode) in which a voltage is applied in the direction of the thickness of the liquid crystal layer. Furthermore, the active matrix substrate according to the embodiment of the present invention is also suitably used in a display device (a display device that includes a display medium layer other than the liquid crystal layer) other than the liquid crystal display device. For example, the active matrix substrate according to the embodiment of the present invention is also used in an electrophoretic display device or an organic electroluminescence (EL) display device, or the like.

### INDUSTRIAL APPLICABILITY

According to the embodiment of the present invention, a drive capability of an oxide semiconductor TFT that is used in a semiconductor device can be improved. The semiconductor device according to the embodiment of the present invention is suitably used, for example, as an active matrix substrate for a display device.

### REFERENCE SIGNS LIST

1 SUBSTRATE
2, 2′ FIRST GATE ELECTRODE (LOWER LAYER GATE ELECTRODE)
3 FIRST GATE INSULATING LAYER (LOWER LAYER GATE INSULATING LAYER)
4 FIRST OXIDE SEMICONDUCTOR LAYER (LOWER LAYER OXIDE SEMICONDUCTOR LAYER)
5 FIRST SOURCE ELECTRODE (LOWER LAYER SOURCE ELECTRODE)
6 FIRST DRAIN ELECTRODE (LOWER LAYER DRAIN ELECTRODE)
7 SECOND GATE INSULATING LAYER (INTERMEDIATE LAYER GATE INSULATING LAYER)
8 SECOND GATE ELECTRODE (UPPER LAYER GATE ELECTRODE)
9 THIRD GATE INSULATING LAYER (UPPER LAYER GATE INSULATING LAYER)
10 SECOND OXIDE SEMICONDUCTOR LAYER (UPPER LAYER OXIDE SEMICONDUCTOR LAYER)
11 SECOND SOURCE ELECTRODE (UPPER LAYER SOURCE ELECTRODE)
12, 12′ SECOND DRAIN ELECTRODE (UPPER LAYER DRAIN ELECTRODE)
13 PROTECTIVE LAYER (PASSIVATION LAYER)
14 DIELECTRIC LAYER
15 CRYSTALLINE SILICON SEMICONDUCTOR LAYER
16 GATE INSULATING LAYER
17 GATE ELECTRODE
18 SOURCE ELECTRODE
19 DRAIN ELECTRODE
20A, 20A′, 20B1, 20B2 OXIDE SEMICONDUCTOR TFT
20C CRYSTALLINE SILICON TFT
30 TFT (PIXEL TFT)
40, 40M GATE DRIVER
50 SOURCE DRIVER
60 FPC SUBSTRATE
100A, 100B, 100C, 100D SEMICONDUCTOR DEVICE
200 ACTIVE MATRIX SUBSTRATE
DR DISPLAY AREA
FR NON-DISPLAY AREA
P PIXEL AREA (PIXEL)
GL GATE WIRING LINE
SL SOURCE WIRING LINE
PE PIXEL ELECTRODE
CE COMMON ELECTRODE

1. A semiconductor device comprising:
a substrate;
a first gate electrode that is provided on the substrate;
a first gate insulating layer that covers the first gate electrode;
a first oxide semiconductor layer that is provided on the first gate insulating layer and faces the first gate electrode with the first gate insulating layer in between;
a first source electrode and a first drain electrode that are electrically connected to the first oxide semiconductor layer;
a second gate insulating layer that covers the first oxide semiconductor layer;
a second gate electrode that is provided on the second gate insulating layer and faces the first oxide semiconductor layer with the second gate insulating layer in between;
a third gate insulating layer that covers the second gate electrode;
a second oxide semiconductor layer that is provided on the third gate insulating layer and faces the second gate electrode with the third gate insulating layer in between; and
a second source electrode and a second drain electrode that are electrically connected to the second oxide semiconductor layer.

2. The semiconductor device according to claim 1,
wherein the first source electrode and the second source electrode are electrically connected to each other, and
wherein the first drain electrode and the second drain electrode are electrically connected to each other.

3. The semiconductor device according to claim 2,
wherein the first gate electrode, the first gate insulating layer, the first oxide semiconductor layer, the first source electrode, the first drain electrode, the second gate insulating layer, the second gate electrode, the third gate insulating layer, the second oxide semiconductor layer, the second source electrode, and the second drain electrode function as one oxide semiconductor TFT that includes the first oxide semiconductor layer and the second oxide semiconductor layer as an activation layer.

4. The semiconductor device according to claim 1,
wherein the first source electrode and the second source electrode are not electrically connected to each other, and
wherein the first drain electrode and the second drain electrode are not electrically connected to each other.

5. The semiconductor device according to claim 4,
wherein the first gate electrode, the first gate insulating layer, the first oxide semiconductor layer, the first source electrode, the first drain electrode, the second gate insulating layer, and the second gate electrode function as a first oxide semiconductor TFT that includes the first oxide semiconductor layer as an activation layer, and
wherein the second gate electrode, the third gate insulating layer, the second oxide semiconductor layer, the second source electrode, and the second drain electrode function as a second oxide semiconductor TFT that includes the second oxide semiconductor layer as an activation layer.

6. The semiconductor device according to claim 1,
wherein the first source electrode and the second source electrode are electrically connected to each other, and
wherein the first drain electrode and the second drain electrode are not electrically connected to each other.

7. The semiconductor device according to claim 1,
wherein the first source electrode and the second source electrode are not electrically connected to each other, and
wherein the first drain electrode and the second drain electrode are electrically connected to each other.

8. The semiconductor device according to claim 1, further comprising:
a crystalline silicon TFT that includes a crystalline silicon semiconductor layer as an activation layer.

9. The semiconductor device according to claim 8,
wherein the crystalline silicon TFT includes
the crystalline silicon semiconductor layer that is provided in the substrate,
the first gate insulating layer that covers the crystalline silicon semiconductor layer,
a third gate electrode that is provided on the first gate insulating layer and faces the crystalline silicon semiconductor layer with the first gate insulating layer in between, and
a third source electrode and a third drain electrode that are electrically connected to the crystalline silicon semiconductor layer.

10. The semiconductor device according to claim 8,
wherein the first gate electrode is formed from an identical crystalline silicon film with the crystalline silicon semiconductor layer.

11. The semiconductor device according to claim 1,
wherein each of the first oxide semiconductor layer and the second oxide semiconductor layer contains an In—Ga—Zn—O-based semiconductor.

12. The semiconductor device according to claim 11,
wherein the In—Ga—Zn—O-based semiconductor contains a crystalline portion.

13. The semiconductor device according to claim 1, which is an active matrix substrate that has a display area which includes multiple pixel areas and a non-display area which is positioned in a vicinity of the display area.

14. The semiconductor device according to claim 3, which is an active matrix substrate that has a display area which includes multiple pixel areas and a non-display area which is positioned in a vicinity of the display area,
wherein the oxide semiconductor TFT is positioned in each of the multiple pixel areas.

15. The semiconductor device according to claim 8, which is an active matrix substrate that has a display area which includes multiple pixel areas and a non-display area which is positioned in a vicinity of the display area,
wherein the crystalline silicon TFT is positioned in the non-display area.

16. A display device comprising:
an active matrix substrate;
a counter substrate that is positioned in such a manner as to face the active matrix substrate; and
a display medium layer that is provided between the active matrix substrate and the counter substrate,
wherein the active matrix substrate is the semiconductor device as in claim 13.
